(19) United States
(12) Patent Application Publication
(10) Pub. No.: US 2024/0017989 A1
(43) Pub. Date: Jan. 18, 2024

(54) MEMS DEVICE AND METHOD OF MANUFACTURING MEMS DEVICE

(71) Applicant: ROHM CO., LTD., Kyoto (JP)

(72) Inventor: Martin Wilfried HELLER, Kyoto (JP)

(73) Assignee: ROHM CO., LTD., Kyoto (JP)

(21) Appl. No.: 18/348,664

(22) Filed: Jul. 7, 2023

(30) Foreign Application Priority Data
Jul. 15, 2022 (JP) 2022-114035

(51) Int. Cl. B81C 1/00; B81B 7/02

(52) U.S. Cl. CPC B81C 1/00166; B81B 7/02; B81B 2201/0235; B81B 2203/0315; B81B 2203/033; B81B 2203/04; B81C 2201/0132; B81C 2201/0177; B81C 2201/019; B81C 2201/0178

(57) ABSTRACT

A MEMS device includes a substrate which has a first main surface and a second main surface facing the first main surface, and in which a silicon substrate, a silicon carbide layer having conductivity, and a silicon layer are sequentially stacked from a second main surface side toward a first main surface side, a cavity recessed over the silicon layer, the silicon carbide layer, and the silicon substrate from the first main surface of the substrate to the second main surface side of the substrate, a MEMS electrode which is arranged in the cavity, is composed of the silicon layer and the silicon carbide layer, and is spaced apart from a bottom surface of the cavity to the first main surface side, and an isolation joint which divides the MEMS electrode in a plan view and mechanically connects and electrically isolates both sides of the divided MEMS electrode.

### CROSS-REFERENCE TO RELATED APPLICATION

This application is based upon and claims the benefit of priority from Japanese Patent Application No. 2022-114035, filed on Jul. 15, 2022, the entire contents of which are incorporated herein by reference.

### TECHNICAL FIELD

The present disclosure relates to a MEMS device and a method of manufacturing the MEMS device.

### BACKGROUND

In the related art, a MEMS (Micro Electro Mechanical System) sensor having a MEMS electrode, as a MEMS device manufactured using semiconductor micro-fabrication technology, has been disclosed. For example, the MEMS electrode is formed by a SCREAM (Single Crystal Silicon Reactive Etch and Meal) method. According to the SCREAM method, first, trenches are formed in a substrate (for example, a silicon substrate) along contours of the MEMS electrode in a plan view, and the substrate is removed from the bottoms of the trenches by isotropic etching, so that a cavity in which the bottoms of adjacent trenches are connected to each other can be formed and the MEMS electrode can be released from the bottom surface of the cavity.

### BRIEF DESCRIPTION OF DRAWINGS

The accompanying drawings, which are incorporated in and constitute a part of the specification, illustrate embodiments of the present disclosure.

FIG. 1 is a plan view of an acceleration sensor according to an embodiment of the present disclosure.

FIG. 2 is a cross-sectional view of the acceleration sensor, which is taken along line II-II in FIG. 1.

FIG. 3 is a view showing a part of a process of manufacturing an acceleration sensor according to an embodiment of the present disclosure.

FIG. 4 is a view showing a next step of FIG. 3.

FIG. 5 is a view showing a next step of FIG. 4.

FIG. 6 is a view showing a next step of FIG. 5.

FIG. 7 is a view showing a next step of FIG. 6.

FIG. 8 is a view showing a next step of FIG. 7.

FIG. 9 is a view showing a next step of FIG. 8.

FIG. 10 is a view showing a next step of FIG. 9.

FIG. 11 is a view showing a next step of FIG. 10.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

A MEMS device according to an embodiment of the present disclosure will be described below with reference to the accompanying drawings. It should be noted that the following description is essentially no more than an example and is not intended to limit the present disclosure, its applications, or its uses. Moreover, the drawings are schematic, and the ratio of each dimension is different from the actual one.

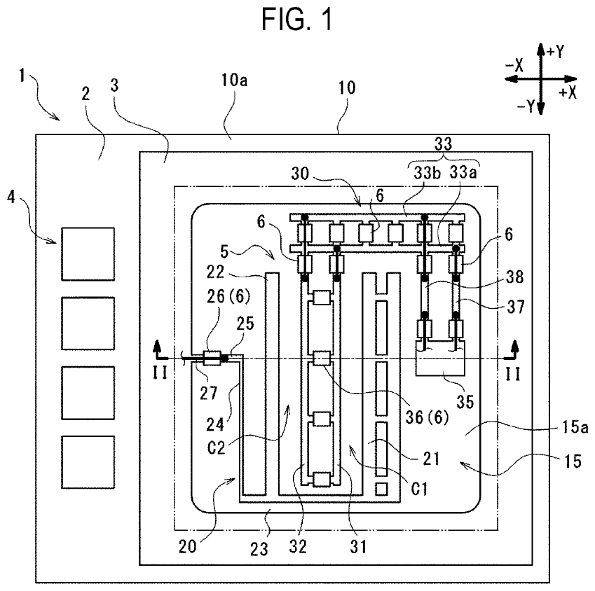

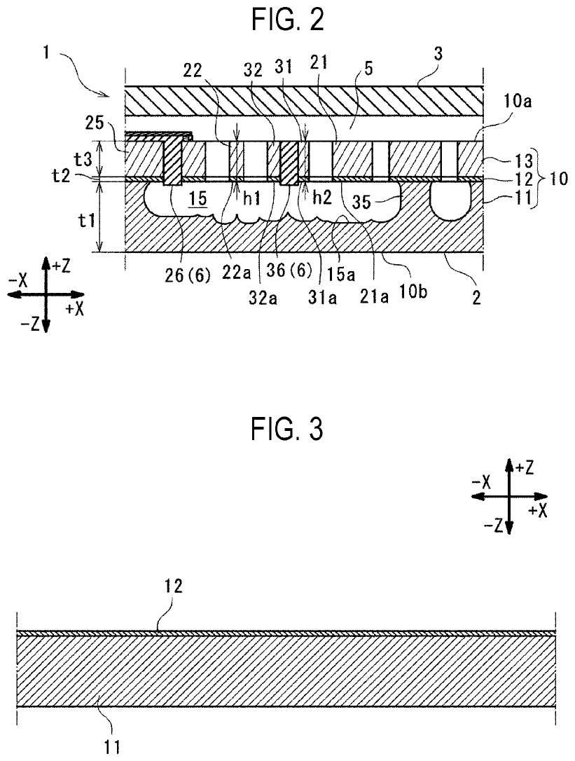

FIG. 1 is a plan view schematically showing an acceleration sensor 1 according to an embodiment of the present disclosure. FIG. 2 is a cross-sectional view taken along line II-II in FIG. 1. The acceleration sensor 1 according to this embodiment is a capacitive acceleration sensor manufactured using semiconductor micro-fabrication technology. Referring to FIGS. 1 and 2, the acceleration sensor 1 includes a device-side substrate assembly 2 having a MEMS electrode 5, and a lid-side substrate assembly 3 that is bonded to the device-side substrate assembly 2 to form an accommodation space for accommodating the MEMS electrode 5 between the device-side substrate assembly 2 and the lid-side substrate assembly 3. In FIG. 1, the inside of the lid-side substrate assembly 3 surrounded by a two-dot chain line is in a transparent state, and the MEMS electrode 5 is shown transparently.

In the following descriptions, for the sake of convenience, among directions along each side of the acceleration sensor 1 in a plan view shown in FIG. 1, the horizontal direction in FIG. 1 is referred to as an X direction, and the vertical direction in FIG. 1 is referred to as a Y direction. Further, the thickness direction of the acceleration sensor 1 (the vertical direction in FIGS. 2 to 11) in each cross-sectional view shown in FIGS. 2 to 11 is referred to as a Z direction. In particular, in FIG. 1, the right side is referred to as a +X direction, the left side as a −X direction, the upper side as a +Y direction, and the lower side as a −Y direction. In FIGS. 2 to 11, the upper side is referred to as a +Z direction and the lower side is referred to as called a −Z direction.

As shown in FIG. 1, the device-side substrate assembly 2 includes a substrate 10, a MEMS electrode 5 provided in the substrate 10, and a plurality of electrode pads 4 for inputting/outputting electric signals (voltages) to/from the MEMS electrode.

The substrate 10 has a first main surface 10a located on the +Z side and a second main surface 10b located on the −Z side and facing the first main surface 10a (see FIG. 2). The first main surface 10a and the second main surface 10b extend in parallel to the X direction and the Y direction. The substrate 10 includes a first layer 11 having the second main surface 10b on the −Z side, a second layer 12 stacked on the +Z side of the first layer 11, and a third layer 13 stacked on the +Z side of the second layer 12 and having the first main surface 10a on the +Z side.

The first layer 11 is a conductive silicon substrate and constitutes a handle wafer of the substrate 10. In this embodiment, the first layer 11 is a conductive p-type silicon substrate that is doped with p-type impurities such as boron at a high concentration (for example, 10¹⁸ to 10²⁰/cm³) to impart conductivity. In this embodiment, the first layer 11 has a thickness t1 of 700 μm.

The second layer 12 is a conductive silicon carbide (SiC) layer. In this embodiment, the second layer 12 is a p-type silicon carbide epitaxial growth layer formed so as to impart conductivity by performing epitaxial growth of silicon carbide on the first layer 11 while doping p-type impurities such as boron at a high concentration (for example, 10¹⁸ to 10²⁰/cm³). In this embodiment, the second layer 12 has a thickness t2 of 100 nm or more and 600 nm or less.

The third layer 13 is a conductive silicon (Si) layer. In this embodiment, the third layer 13 is a p-type silicon epitaxial growth layer formed so as to impart conductivity by performing epitaxial growth of silicon on the second layer 12 while doping p-type impurities such as boron at a high concentration (for example, 10¹⁸ to 10²⁰/cm³). In this embodiment, the third layer 13 has a thickness t3 of 15 μm or more and 20 μm or less.

The substrate 10 is formed with a cavity 15 that is rectangular in a plan view and is recessed on the −Z side from the first main surface 10a to the middle of the first layer 11 by passing through the third layer 13 and the second layer 12.

Hereinafter, the MEMS electrode 5 will be described in detail. The MEMS electrode 5 includes a movable electrode 20 and a fixed electrode 30, which are arranged within the cavity 15. The movable electrode 20 is spaced apart from the bottom surface 15a of the cavity 15 (hereinafter referred to as a cavity bottom surface 15a) on the +Z side. The fixed electrode 30 is spaced apart from the cavity bottom surface 15a on the +Z side except for a fixed electrode support portion 35 which will be described later.

As shown in FIG. 1, the movable electrode 20 includes a first movable electrode element 21 located on the +X side of the cavity 15 and extending in the Y direction, a second movable electrode element 22 located on the −X side of the first movable electrode element 21 and extending in the Y direction, a movable electrode base portion 23 connected to the −Y side ends of the first movable electrode element 21 and the second movable electrode element 22 and extending in the X direction, a movable electrode support portion 25 extending from the inner wall surface on the −X side of the cavity 15 to the +X side, and a movable electrode spring portion 24 connecting the movable electrode support portion 25 and the movable electrode base portion 23.

The first movable electrode element 21 is configured to be wider in the X direction than the second movable electrode element 22 and has a proof mass. When acceleration in the X direction acts on the movable electrode 20, the movable electrode spring portion 24 elastically deforms, thereby displacing the first movable electrode element 21 and the second movable electrode element 22 in the X direction.

As shown in FIG. 2, the first movable electrode element 21 and the second movable electrode element 22 are configured over the third layer 13 and the second layer 12, and the bottom surfaces 21a and 22a of the first movable electrode element 21 and the second movable electrode element 22 are configured by the interface of the second layer 12 with the first layer 11, and thus are parallel to the first main surface 10a or the second main surface 10b. In other words, the first movable electrode element 21 and the second movable electrode element 22 do not have a portion constituted by the first layer 11. Therefore, the first movable electrode element 21 and the second movable electrode element 22 are configured to have a height h1 which is a dimension in the Z direction from the first main surface 10a to the bottom surfaces 21a and 22a, is approximately equal to the sum of the thickness t3 of the third layer 13 and the thickness t2 of the second layer 12, and is substantially uniform in its entirety.

Similarly, the movable electrode base portion 23, the movable electrode spring portion 24, and the movable electrode support portion 25 are also configured over the third layer 13 and the second layer 12, but do not have a portion constituted by the first layer 11. Therefore, the movable electrode base portion 23, the movable electrode spring portion 24, and the movable electrode support portion 25 are configured to have substantially a uniform height h1 in the Z direction which is the same height as the first movable electrode element 21 and the second movable electrode element 22.

As shown in FIGS. 1 and 2, the movable electrode 20 further includes a movable electrode isolation joint 26 that crosses the movable electrode support portion 25 in the Y and Z directions and divides it in the X direction. The movable electrode isolation joint 26 penetrates the movable electrode support portion 25 in the Z direction and protrudes toward the −Z side. The −Z-side end of the movable electrode isolation joint 26 is spaced apart from the cavity bottom surface 15a on the +Z side.

The movable electrode isolation joint 26 is silicon oxide formed by thermally oxidizing at least the third layer 13 in this embodiment, but may additionally have portions where the second layer 12 and the first layer 11 are thermally oxidized. The movable electrode isolation joint 26 mechanically connects and electrically isolates both sides of the movable electrode support portion 25 which are separated in the X direction by the movable electrode isolation joint 26.

A movable electrode wiring layer 27 is connected to the +X-side portion of the movable electrode isolation joint 26 in the movable electrode support portion 25. The movable electrode 20 is electrically connected to one of the plurality of electrode pads 4 via the movable electrode wiring layer 27.

As shown in FIG. 1, the fixed electrode 30 includes a first fixed electrode element 31 that is located between the first movable electrode element 21 and the second movable electrode element 22, faces the first movable electrode element 21, and extends in the Y direction, a second fixed electrode element 32 that is located on the −X side of the first fixed electrode element 31, faces the second movable electrode element 22, and extends in the Y direction, a fixed electrode support portion 35 that protrudes from the cavity bottom surface 15a to the +Z side at a position from the +X side of the cavity 15, and a fixed electrode connection portion 33 that connects the +Y side-ends of the first fixed electrode element 31 and the second fixed electrode element 32 to the fixed electrode support portion 35.

As shown in FIG. 2, the first fixed electrode element 31 and the second fixed electrode element 32 are configured over the third layer 13 and the second layer 12, and the bottom surfaces 31a and 32a of the first fixed electrode element 31 and the second fixed electrode element 32 are configured by the interface of the second layer 12 with the first layer 11 and thus are parallel to the first main surface 10a or the second main surface 10b. In other words, the first fixed electrode element 31 and the second fixed electrode element 32 do not have a portion constituted by the first layer 11. Therefore, the first fixed electrode element 31 and the second fixed electrode element 32 are configured to have a height h2 which is a dimension in the Z direction from the first main surface 10a to the bottom surfaces 31a and 32a, is approximately equal to the sum of the thickness t3 of the third layer 13 and the thickness t2 of the second layer 12, and is substantially uniform in its entirety. The height h2 of the first fixed electrode element 31 and the second fixed electrode element 32 is approximately equal to the height h1 of the first movable electrode element 21 and the second movable electrode element 22.

Similarly, the fixed electrode connection portion 33 is configured over the third layer 13 and the second layer 12, but does not have a portion constituted by the first layer 11. Therefore, the height of the fixed electrode connection portion 33 in the Z direction is substantially uniform at h2 which is the same height as the first fixed electrode element 31 and the second fixed electrode element 32.

The fixed electrode 30 further includes a fixed electrode isolation joint 36 that mechanically connects and electrically isolates the first fixed electrode element 31 and the second fixed electrode element 32 in the X direction. The fixed electrode isolation joint 36 protrudes from the first fixed electrode element 31 and the second fixed electrode element 32 to the −Z side. The −Z-side end of the fixed electrode isolation joint 36 is spaced apart from the cavity bottom surface 15a on the +Z side.

The fixed electrode isolation joint 36 is silicon oxide formed by thermally oxidizing at least the third layer 13 in this embodiment, but may additionally have portions where the second layer 12 and the third layer 13 are thermally oxidized.

As shown in FIG. 1, the fixed electrode connection portion 33 includes a first connection portion 33a electrically connected to the first fixed electrode element 31, and a second connection portion 33b electrically connected to the second fixed electrode element 32. The first connection portion 33a and the second connection portion 33b are electrically insulated from each other. A first fixed electrode wiring layer 37 is connected to the first connection portion 33a and is electrically connected to one of the plurality of electrode pads 4 via the first fixed electrode wiring layer 37. Similarly, a second fixed electrode wiring layer 38 is connected to the second connection portion 33b and is electrically connected to one of the plurality of electrode pads 4 via the second fixed electrode wiring layer 38.

As shown in FIG. 2, the fixed electrode support portion 35 extends from the cavity bottom surface 15a to the +Z side over the first layer 11, the second layer 12, and the third layer 13.

In the MEMS electrode 5, a first capacitor C1 is constituted by the first movable electrode element 21 and the first fixed electrode element 31, and a second capacitor C2 is constituted by the second movable electrode element 22 and the second fixed electrode element 32. The acceleration sensor 1 is configured to be capable of detecting acceleration by taking out a change in the capacitance of each of the first and second capacitors C1 and C2, which is accompanied with the displacement of the movable electrode 20 in the X direction when the acceleration acts, as an electric signal from the electrode pads 4.

Next, a method of manufacturing the acceleration sensor 1 will be described. A method of manufacturing the device-side substrate assembly 2 in the method of manufacturing the acceleration sensor 1 will be described with reference to FIGS. 3 to 11. As shown in FIG. 3, first, the first layer 11, which is a conductive silicon substrate, is prepared. The first layer 11 constitutes the handle wafer of the substrate 10 and is, for example, a p-type conductive silicon wafer. The thickness t1 (see FIG. 2) of the first layer 11 is, for example, 700 μm.

The second layer 12, which is a p-type silicon carbide epitaxial growth layer, is formed by performing epitaxial growth of silicon carbide on the first layer 11 (the +Z side) while doping p-type impurities such as boron at a high concentration (for example, 10¹⁸ to 10²⁰/cm³). The second layer 12 is formed by the epitaxial growth until its thickness t2 (see FIG. 2) becomes 100 nm or more and 600 nm or less.

A silicon carbide layer is formed, for example, by LPCVD (Low Pressure Chemical Vapor Deposition). As an example of conditions for forming the silicon carbide layer, trichlorosilane (TCS) is used as a silicon species, and a gas containing ethylene, hydrogen, and a p-type dopant is used to perform epitaxial growth of the silicon carbide layer under the conditions of 100 mbar and 1,400 degrees C. The formed silicon carbide layer can have one of 3C, 4H, or 6H crystal structures depending on the conditions of performing the epitaxial growth.

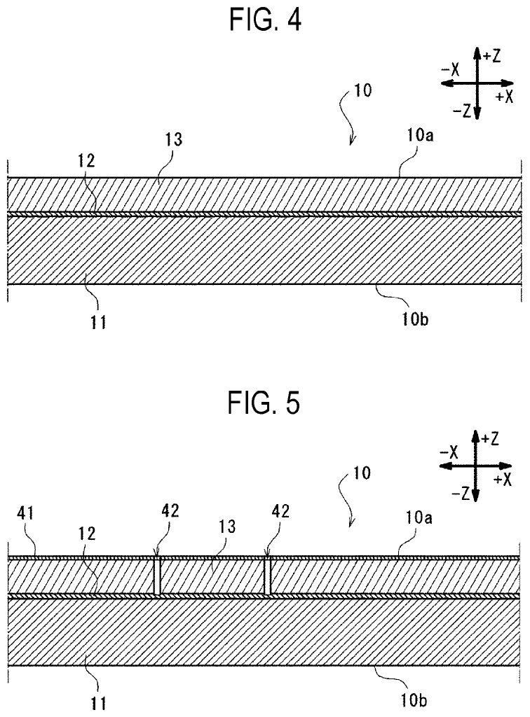

Next, as shown in FIG. 4, the third layer 13, which is a p-type silicon epitaxial growth layer, is formed by performing epitaxial growth of silicon (Si) on the second layer 12 (the +Z side) while doping p-type impurities such as boron at a high concentration (for example, 10¹⁸ to 10²⁰/cm³). The third layer 13 is formed by the epitaxial growth until its thickness t3 (see FIG. 2) is 15 μm or more and 20 μm or less.

In this embodiment, the second layer 12 and the third layer 13 may be continuously formed by switching a gas while performing a series of the epitaxial growth. However, the formation of the second layer 12 and the formation of the third layer 13 may be performed separately.

Next, as shown in FIG. 5, a first silicon oxide layer (SiO₂) 41 exposed at a position corresponding to the movable electrode isolation joint 26 and the fixed electrode isolation joint 36 (hereinafter, sometimes collectively referred to as an isolation joint 6) is formed on the first main surface 10a of the substrate 10. In this embodiment, the first silicon oxide layer 41 has a thickness of 500 nm. Next, by using the first silicon oxide layer 41 as a hard mask, a first trench 42 is formed by digging the substrate 10 from the first main surface 10a toward the −Z side by anisotropic etching.

Here, in the substrate 10, the second layer 12 is located on the −Z side of the third layer 13. Since the second layer 12 is a silicon carbide layer, it acts as an etching stop layer that significantly lowers the etching rate as compared to the etching rate of the first layer 11 which is a silicon layer. Therefore, after the −Z-side end of the first trench 42 penetrates the first layer 11, the first trench 42 stops at the +Z-side surface of the second layer 12 or at a position where the second layer 12 is slightly dug down.

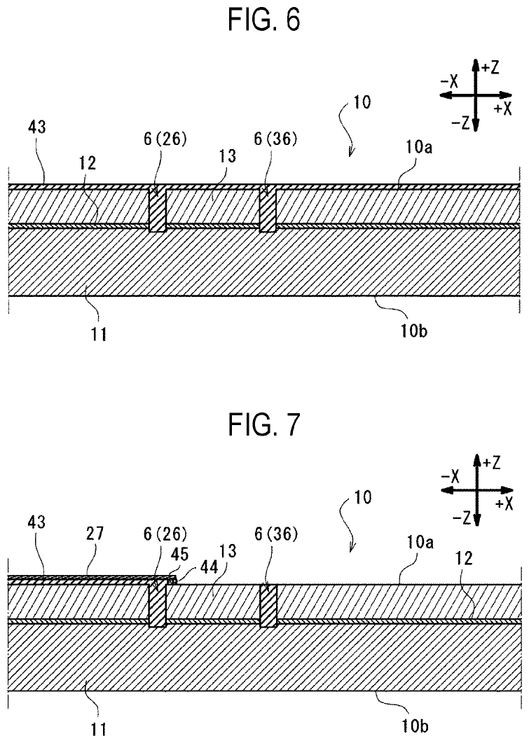

Next, as shown in FIG. 6, after removing the first silicon oxide layer 41 from the substrate 10, by thermally oxidizing the substrate 10 from the +Z side, a thermally-oxidized film 43 of thermally-oxidized silicon is formed on the first main surface 10a and the inner wall surface of the first trench 42. The thermally-oxidized film 43 formed on the inner wall surface of the first trench 42 substantially fills the inside of the first trench 42 and expands outward, while the thermally-oxidized film 43 grows in the −Z direction so that the bottom of the thermally-oxidized film 43 penetrates the second layer 12 and bites into the first layer 11, thereby forming the isolation joint 6.

As the isolation joint 6 grows to the −Z side, the second layer 12, which is silicon carbide, and the first layer 11, which is a silicon substrate, are also thermally oxidized to become silicon oxide which forms a portion of the isolation joint 6.

Next, as shown in FIG. 7, in the thermally-oxidized film 43 formed on the first main surface 10a of the substrate 10, a portion located on the +X side of the movable electrode isolation joint 26 is removed. Further, a contact hole 44 penetrating in the Z direction and communicating with the first layer 11 is formed in a portion of the thermally-oxidized film 43 remaining without being removed, which is located on the +X side of the movable electrode isolation joint 26, and the contact hole 44 is filled with a contact 45 made of conductive metal.

Next, the movable electrode wiring layer 27 electrically connected to the contact 45 is patterned on the +Z-side surface of the remaining thermally-oxidized film 43. That is, the movable electrode wiring layer 27 is electrically connected to the third layer 13 via the conductive contact 45. Further, although not shown, a plurality of electrode pads 4, a first fixed electrode wiring layer 37a, a second fixed electrode wiring layer 37b, a passivation layer, and the like are formed on the +Z side of the third layer 13.

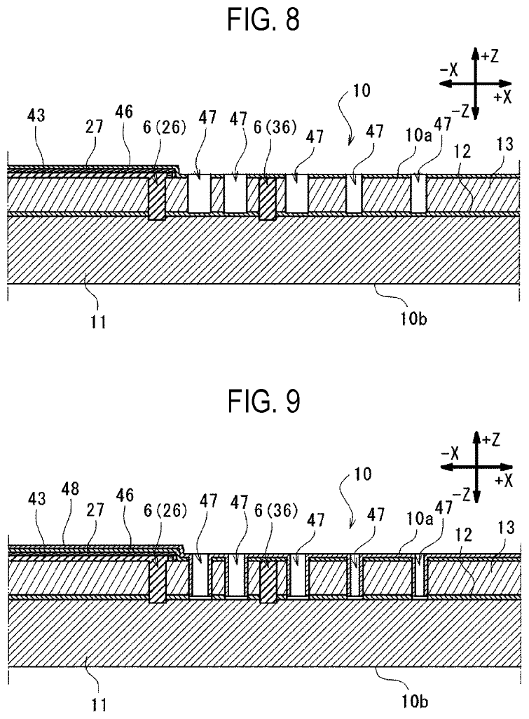

Next, as shown in FIG. 8, a second silicon oxide layer (SiO₂) 46 is formed on the first main surface 10a of the substrate 10 in a portion corresponding to the MEMS electrode 5. Next, by using the second silicon oxide layer 46 as a hard mask, a second trench 47 is formed by digging the substrate 10 from the first main surface 10a toward the −Z side by anisotropic etching. Similar to the formation of the first trench 42, since the second layer 12 acts as an etching stop layer, after the −Z-side end of the second trench 47 penetrates the first layer 11, the second trench 47 stops at the +Z side surface of the second layer 12 or at a position where the second layer 12 is slightly dug down.

Next, as shown in FIG. 9, a third silicon oxide layer 48 is formed on the second silicon oxide layer 46 and the inner wall surface of the second trench 47. The third silicon oxide layer 48 is removed at the bottom of the second trench 47. Next, the second layer 12 is removed by etching the bottom of the second trench 47 to reveal the first layer 11 at the bottom of the second trench 47. The removal of the second layer 12 is performed, for example, by etching using sulfur hexafluoride (SF 6) and oxygen as etching gases at a higher temperature (for example, 200 to 300 degrees C.).

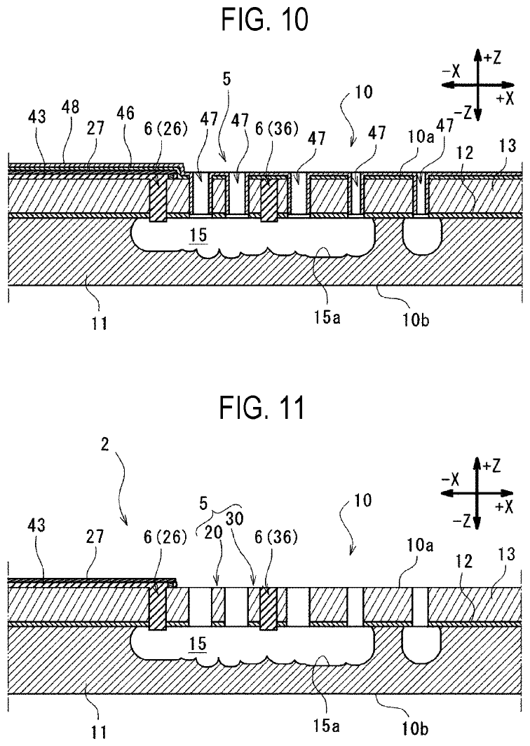

Next, as shown in FIG. 10, the first layer 11 located on the −Z side of the MEMS electrode 5 and the isolation joint 6 is removed by removing the bottom of the second trench 47 by isotropic etching, and by connecting the bottoms of the adjacent second trenches 47 to each other, the cavity 15 is formed, and the MEMS electrode 5 is formed so as to be spaced apart (also called released) from the cavity bottom surface 15a to the +Z side. At this time, the second layer 12 is not removed by etching and remains at the −Z side end of the MEMS electrode 5.

Next, as shown in FIG. 11, the device-side substrate assembly 2 is formed by removing the second silicon oxide layer 46 and the third silicon oxide layer 48. Although the description is omitted, the lid-side substrate assembly 3 is similarly formed by a MEMS process. The acceleration sensor 1 is manufactured by bonding the device-side substrate assembly 2 and the lid-side substrate assembly 3 together.

The above-described acceleration sensor 1 according to the present embodiment has the following effects.

(1) The acceleration sensor 1 includes: a substrate 10 which has a first main surface 10a and a second main surface 10b facing the first main surface 10a, and in which a first layer 11, which is a silicon substrate, a second layer 12, which is a conductive silicon carbide layer, and a third layer 13, which is a silicon layer, are sequentially stacked from the second main surface side toward the first main surface 10a side; a cavity 15 recessed over the third layer 13, the second layer 12, and the first layer 11 from the first main surface 10a to the second main surface side of the substrate 10; a MEMS electrode 5, which is arranged in the cavity 15, is composed of the third layer 13 and the second layer 12, and is spaced apart from the cavity bottom surface 15a to the first main surface 10a side; and an isolation joint 6 which divides the MEMS electrode 5 in a plan view and mechanically connects and electrically isolates both sides of the divided MEMS electrode 5.

That is, a method of manufacturing the acceleration sensor 1, includes: forming a substrate 10 by preparing a first layer 11, which is a silicon substrate, stacking a second layer 12, which is a silicon carbide layer, on the first layer 11, and stacking a third layer 13, which is a silicon layer, on the second layer 12, wherein the substrate 10 has a first main surface 10a which is an outer surface of the third layer 13 and a second main surface 10b facing the first main surface 10a which is an outer surface of the first layer 11; forming an isolation joint 6 by forming a first trench 42 in the substrate 10 from the first main surface 10a to the second layer 12 and thermally oxidizing the wall surface and bottom surface of the first trench 42, wherein the isolation joint 6 has a portion where the third layer 13, which is the silicon layer, is thermally oxidized and a portion where the second layer 12, which is the silicon carbide layer, is thermally oxidized; forming a second trench 47 in the substrate 10 from the first main surface 10a to the second layer 12 and partitioning a MEMS electrode 5 at least in the third layer 13 by the second trench 47 in a plan view, wherein the MEMS electrode 5 partitioned in a plan view is divided by the isolation joint 6 in a plan view; and forming a cavity 15 by removing the first layer 11 located on the second main surface 10b side of the partitioned MEMS electrode 5, and forming the MEMS electrode 5 spaced apart from the cavity bottom surface 15a, wherein both sides of the MEMS electrode 5 divided by the isolation joint 6 are mechanically connected and electrically isolated by the isolation joint 6.

As a result, since the MEMS electrode 5 can be configured to extend from the first main surface 10a to the second layer 12 which is the silicon carbide layer, the height of the MEMS electrode 5 in the Z direction can be made uniform.

Further, the isolation joint 6 can be constructed integrally as silicon oxide over the third layer 13 and the second layer 12 by thermally oxidizing the inner wall surfaces of the first trench 42 and the second trench 47 formed from the third layer 13, which is the silicon layer, to the second layer 12, which is the silicon carbide layer.

Furthermore, the first layer 11 and the third layer 13 located on both sides of the second layer 12 interposed therebetween in the Z direction can be electrically connected to each other by the conductive second layer 12. Therefore, charging between the first layer 11 and the third layer 13 is suppressed. Moreover, since the second layer 12 is a conductive silicon carbide layer, it is difficult to accumulate electric charges on the surface of the second layer 12, and the lower surface (silicon carbide layer) of the MEMS electrode 5 is prevented from being attracted to the cavity bottom surface 15a by an electrostatic attractive force.

In order to make the height of the MEMS electrode 5 uniform, it is conceivable to employ SOI (Silicon On Insulator) having a silicon oxide layer as an etching stop layer in the second layer as the substrate. However, in this case, since the bottom of the trench is composed of the second layer, which is the silicon oxide layer, it is difficult to thermally oxidize the bottom of the trench, so that it is difficult to form the isolation joint so as to penetrate the second layer in the Z direction.

Further, when the −Z-side end portion of the MEMS electrode 5 is composed of the second layer, which is the silicon oxide layer, the surface of the MEMS electrode 5 is easily electrified, and the electrified electric charges may be attracted and adhere to the cavity bottom surface 15a. Therefore, when SOI is used for the substrate, it is necessary to remove the second layer at the bottom of the MEMS electrode 5, but at this time, the isolation joints also made of silicon oxide are also removed (also called overetching).

Furthermore, when the second layer is silicon oxide, the second layer electrically insulates between the first layer and the third layer so that capacitance accumulates in a capacitor formed by the first layer and the third layer. Therefore, in order to electrically connect the first layer and the third layer to each other, it is necessary to form a contact or the like to electrically connect the first layer and the third layer to each other in the second layer.

Therefore, by forming the second layer 12 with conductive silicon carbide as in the present embodiment, the above-described problem in SOI having the silicon oxide layer as the second layer can be solved. That is, when the isolation joint 6 is formed, it is possible for the isolation joint 6 to grow so as to protrude to the −Z side through the second layer 12 by thermally oxidizing the second layer 12, which is the silicon carbide layer. Further, the bottom of the MEMS electrode 5 is composed of the second layer 12 which is silicon carbide, but since the silicon carbide has electrical conductivity, like the silicon oxide layer, electric charges do not accumulate on the surface of the second layer 12 and are not attracted to the cavity bottom surface 15a. Furthermore, since the second layer 12 has electrical conductivity, it can electrically connect the first layer 11 and the third layer 13 to each other without providing a separate contact layer.

(2) The second layer 12, which is the silicon carbide layer, is an etching stop layer when etching the third layer 13 from the first main surface 10a to the second main surface 10b side. As a result, when forming the trench by etching the third layer 13, which is the silicon layer, from the first main surface 10a to the second main surface 10b side, since the etching rate is lower in the second layer 12 (silicon carbide layer) than when etching the third layer 13 (silicon layer), it is easier to control the etching so that the bottom of the trench terminates at the second layer.

(3) The second layer 12, which is the silicon carbide layer, is an epitaxial growth layer. That is, the second layer 12, which is the silicon carbide layer, is formed by performing epitaxial growth of silicon carbide on the first layer 11 which is the silicon substrate. As a result, the silicon carbide layer can be easily stacked on the first layer 11, which is the silicon substrate, as compared to a case of forming the second layer 12 by bonding a silicon carbide layer prepared as a separate member.

(4) The third layer 13, which is the silicon layer, is an epitaxial growth layer. That is, the third layer 13, which is the silicon layer, is formed by performing epitaxial growth of silicon on the second layer 12 which is the silicon carbide layer. As a result, the silicon layer can be easily stacked on the second layer 12, which is the silicon carbide layer, as compared to a case of forming the third layer 13 by bonding a silicon layer prepared as a separate member.

(5) The isolation joint 6 protrudes from the MEMS electrode 5 to the second main surface side. That is, the thermal oxidation of the first trench 42 is performed such that the isolation joint 6 penetrates the second layer 12, which is the silicon carbide layer, and protrudes to the second main surface 10b side. As a result, both sides of the MEMS electrode 5 divided by the isolation joint 6 can be electrically isolated reliably by the isolation joint 6.

(6) The thickness of the second layer 12, which is the silicon carbide layer, is 100 nm or more and 600 nm or less. As a result, the thickness of the second layer 12 can be appropriately set. Specifically, while the second layer 12 acts as an etching stop layer, it is easy to penetrate the MEMS electrode 5 when releasing it from the cavity 15, whereby an etching gas can be easily supplied to the lower part of the MEMS electrode 5, so that the removability of the first layer 11, which is the silicon substrate, can be easily secured. If the thickness of the second layer 12 is less than 100 nm, it is likely to penetrate the second layer 12 during trench formation, and its function as an etching stop layer is reduced. On the other hand, if the thickness of the second layer 12 exceeds 600 nm, it is difficult to penetrate the second layer 12 when releasing the MEMS electrode 5 from the bottom surface of the cavity, and the removability of the first layer 11 is reduced.

(7) The thickness of the third layer 13, which is the silicon layer, is 15 μm or more and 20 μm or less. As a result, the thickness of the third layer 13 can be appropriately set, and the MEMS electrode 5 can be easily formed.

(8) The formation of the second layer 12, which is the silicon carbide layer, and the formation of the third layer 13, which is the silicon layer, are successively performed by switching a gas in performing the epitaxial growth. As a result, since the formation of the second layer 12, which is the silicon carbide layer, and the formation of the first layer 11, which is the silicon layer, can be continuously performed by switching a gas in a series of performing the epitaxial growth, the substrate 10 can be efficiently formed.

Note that the acceleration sensor 1 according to the present disclosure is not limited to the configuration of the above-described embodiment, and may be modified in various ways.

In the above-described embodiment, the acceleration sensor 1 has been described as an example of the MEMS device, but it can be applied to various types of MEMS devices having MEMS electrodes.

Further, in the above-described embodiment, the case where the second layer 12 and the third layer 13 are respectively formed by epitaxial growth has been described as an example, but the second layer 12 and/or the third layer 13 constructed as separate members may be bonded to form the substrate 10.

### [Supplementary Notes]

A MEMS device and a method of manufacturing the MEMS device according to the present disclosure provide the following aspects.

### [Aspect 1]

A MEMS device including:
a substrate which has a first main surface and a second main surface facing the first main surface, and in which a silicon substrate, a silicon carbide layer having conductivity, and a silicon layer are sequentially stacked from a second main surface side toward a first main surface side;
a cavity recessed over the silicon layer, the silicon carbide layer, and the silicon substrate from the first main surface of the substrate to the second main surface side of the substrate;
a MEMS electrode which is arranged in the cavity, is composed of the silicon layer and the silicon carbide layer, and is spaced apart from a bottom surface of the cavity to the first main surface side; and
an isolation joint which divides the MEMS electrode in a plan view and mechanically connects and electrically isolates both sides of the divided MEMS electrode.

### [Aspect 2]

The MEMS device of Aspect 1, wherein the silicon carbide layer is an etching stop layer when etching the silicon layer from the first main surface to the second main surface side.

### [Aspect 3]

The MEMS device of Aspect 1 or 2, wherein the silicon carbide layer is an epitaxial growth layer.

### [Aspect 4]

The MEMS device of any one of Aspects 1 to 3, wherein the silicon layer is an epitaxial growth layer.

### [Aspect 5]

The MEMS device of any one of Aspects 1 to 4, wherein the isolation joint protrudes from the MEMS electrode to the second main surface side.

### [Aspect 6]

The MEMS device of any one of Aspects 1 to 5, wherein a thickness of the silicon carbide layer is 100 nm or more and 600 nm or less.

### [Aspect 7]

The MEMS device of any one of Aspects 1 to 6, wherein a thickness of the silicon layer is 15 μm or more and 20 μm or less.

### [Aspect 8]

A method of manufacturing a MEMS device, including:
forming a substrate by preparing a silicon substrate, stacking a silicon carbide layer on the silicon substrate, and stacking a silicon layer on the silicon carbide layer, wherein the substrate has a first main surface that is an outer surface of the silicon layer and a second main surface that faces the first main surface and is an outer surface of the silicon substrate;
forming an isolation joint by forming a first trench in the substrate from the first main surface to the silicon carbide layer and thermally oxidizing a wall surface and a bottom surface of the first trench, wherein the isolation joint has a portion where the silicon layer is thermally oxidized and a portion where the silicon carbide layer is thermally oxidized;
forming a second trench in the substrate from the first main surface to the silicon carbide layer, wherein a MEMS electrode is partitioned at least in the silicon layer by the second trench in a plan view, and the MEMS electrode partitioned in a plan view is divided by the isolation joint in a plan view; and
forming a cavity by removing the silicon substrate located on a second main surface side of the partitioned MEMS electrode, and forming the MEMS electrode spaced apart from the bottom surface of the cavity, wherein both sides of the MEMS electrode divided by the isolation joint are mechanically connected and electrically isolated by the isolation joint.

### [Aspect 9]

The method of Aspect 8, wherein the silicon carbide layer is formed by performing epitaxial growth of silicon carbide on the silicon substrate.

### [Aspect 10]

The method of Aspect 8 or 9, wherein the silicon layer is formed by performing epitaxial growth of silicon on the silicon carbide layer.

### [Aspect 11]

The method of Aspect 10, wherein the silicon carbide layer and the silicon layer are continuously formed by switching a gas in the performing the epitaxial growth.

### [Aspect 12]

The method of any one of Aspects 8 to 11, wherein the thermal oxidation of the first trench is performed such that the isolation joint penetrates the silicon carbide layer and protrudes toward the second main surface.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A MEMS device comprising:
a substrate which has a first main surface and a second main surface facing the first main surface, and in which a silicon substrate, a silicon carbide layer having conductivity, and a silicon layer are sequentially stacked from a second main surface side toward a first main surface side;
a cavity recessed over the silicon layer, the silicon carbide layer, and the silicon substrate from the first main surface of the substrate to the second main surface side of the substrate;
a MEMS electrode which is arranged in the cavity, is composed of the silicon layer and the silicon carbide layer, and is spaced apart from a bottom surface of the cavity to the first main surface side; and
an isolation joint which divides the MEMS electrode in a plan view and mechanically connects and electrically isolates both sides of the divided MEMS electrode.

2. The MEMS device of claim 1, wherein the silicon carbide layer is an etching stop layer when etching the silicon layer from the first main surface to the second main surface side.

3. The MEMS device of claim 1, wherein the silicon carbide layer is an epitaxial growth layer.

4. The MEMS device of claim 1, wherein the silicon layer is an epitaxial growth layer.

5. The MEMS device of claim 1, wherein the isolation joint protrudes from the MEMS electrode to the second main surface side.

6. The MEMS device of claim 1, wherein a thickness of the silicon carbide layer is 100 nm or more and 600 nm or less.

7. The MEMS device of claim 1, wherein a thickness of the silicon layer is 15 μm or more and 20 μm or less.

8. A method of manufacturing a MEMS device, comprising:
forming a substrate by preparing a silicon substrate, stacking a silicon carbide layer on the silicon substrate, and stacking a silicon layer on the silicon carbide layer, wherein the substrate has a first main surface which is an outer surface of the silicon layer and a second main surface which faces the first main surface and is an outer surface of the silicon substrate;
forming an isolation joint by forming a first trench in the substrate from the first main surface to the silicon carbide layer and thermally oxidizing a wall surface and a bottom surface of the first trench, wherein the isolation joint has a portion where the silicon layer is thermally oxidized and a portion where the silicon carbide layer is thermally oxidized;
forming a second trench in the substrate from the first main surface to the silicon carbide layer, wherein a MEMS electrode is partitioned at least in the silicon layer by the second trench in a plan view, and the MEMS electrode partitioned in a plan view is divided by the isolation joint in a plan view; and
forming a cavity by removing the silicon substrate located on a second main surface side of the partitioned MEMS electrode, and forming the MEMS electrode spaced apart from a bottom surface of the cavity, wherein both sides of the MEMS electrode divided by the isolation joint are mechanically connected and electrically isolated by the isolation joint.

9. The method of claim 8, wherein the silicon carbide layer is formed by performing epitaxial growth of silicon carbide on the silicon substrate.

10. The method of claim 9, wherein the silicon layer is formed by performing epitaxial growth of silicon on the silicon carbide layer.

11. The method of claim 10, wherein the silicon carbide layer and the silicon layer are continuously formed by switching a gas in the performing the epitaxial growth.

12. The method of claim 8, wherein the thermal oxidation of the first trench is performed such that the isolation joint penetrates the silicon carbide layer and protrudes toward the second main surface.
